(19) United States
(12) Patent Application Publication
(10) Pub. No.: US 2010/0123177 A1
(43) Pub. Date: May 20, 2010

(54) SEMICONDUCTOR MEMORY DEVICE AND METHOD FOR FABRICATING SEMICONDUCTOR MEMORY DEVICE

(75) Inventor: Tohru OZAKI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/620,424

(22) Filed: Nov. 17, 2009

(30) Foreign Application Priority Data
Nov. 17, 2008 (JP) 2008-292978

(51) Int. Cl. H01L 27/115; H01L 21/8247

(52) U.S. Cl. 257/295; 438/3; 257/296; 438/239; 257/E21.664; 257/E27.103

(57) ABSTRACT

According to an aspect of the present invention, there is provided a semiconductor memory device, including a TC unit series-type FeRAM in which a plurality of memory cells, each of the memory cells comprising a memory transistor and a ferroelectric capacitor connected each other in parallel, are serially connected, including, a first electrode over and electrically connected to one of a source and a drain in the memory transistor, a second electrode opposed to the first electrode over and electrically connected to the other of the source and the drain in the memory transistor, a third electrode on both sidewalls of the second electrode other than an under portion of the second electrode, and a ferroelectric film between the first electrode and the two electrodes, the second electrode and the third electrode, wherein the ferroelectric capacitor comprises the first and the third electrode, and the ferroelectric film.

### CROSS REFERENCE TO RELATED APPLICATION

This application is based upon and claims the benefit of priority from the prior Japanese Patent Application No. JP2008-292978, filed Nov. 17, 2008, the entire contents of which are incorporated herein by reference.

### FIELD OF THE INVENTION

The present invention relates to a semiconductor memory device and a method for fabricating the semiconductor memory device, and more particularly, relates to a ferroelectric memory device and a method for fabricating the ferroelectric memory device.

### DESCRIPTION OF THE BACKGROUND

Ferroelectric memory devices in next generation have been developed and have features being highly rewritable and being over five digits of rewriting numbers as compared to a conventional EEPROM and a conventional flash memory. Therefore, the ferroelectric memory devices in next generation aim to realize comparable capacity, speed and cost with a DRAM. The ferroelectric memory devices in next generation include a ferroelectric random access memory (FeRAM), a magnetic random access memory (MRAM), a phase change random access memory (PRAM), a resistive random access memory (ReRAM) or the like.

A TC-unit series-type ferroelectric random access memory (FeRAM) serially connected with memory cells which are connected a memory transistor and a ferroelectric capacitor in parallel is proposed in a field of the FeRAM for increasing an operation margin. In the TC unit series type FeRAM, a three dimensional memory cell structure is proposed in Japanese Patent Publication (Kokai) No. 2008-182083. In the TC unit series type FeRAM, a ferroelectric film is formed to be configured between a first electrode of a square pillar and a second electrode of the square pillar, the first electrode being configured on a one of a source or a drain in a memory transistor, and the second electrode being configured on the other of the source or the drain in the memory transistor. Further, the memory transistor and the ferroelectric capacitor are configured on a gate electrode in the memory transistor. The ferroelectric capacitor is configured with ferroelectric capacitor in parallel.

However, a film thickness of the ferroelectric film is determined by a process size in the TC unit series type FeRAM disclosed in Japanese Patent Publication (Kokai) No. 2008-182083, occurred. Therefore, a variation of the film thickness is large to be a serious problem. The problem is not generated when the ferroelectric capacitor can be set at a operation voltage including overdriving of 50˜60% to a state which is attained to fully saturated region, 90% saturated voltage region (V90) in a case that the variation of the ferroelectric film thickness is a large value, for example, 15%. However, the ferroelectric capacitor is normally used as 20-30% of V90. Accordingly, a variation of the operation voltage is generated due to the variation of the film thickness so that a variation of signals, a reduction of an operation yield and degradation of reliability are generated.

### SUMMARY OF THE INVENTION

According to an aspect of the invention, there is provided, a semiconductor memory device, including a TC unit series-type FeRAM in which a plurality of memory cells, each of the memory cells comprising a memory transistor and a ferroelectric capacitor connected each other in parallel, are serially connected, including, a first electrode over and electrically connected to one of a source and a drain in the memory transistor, a second electrode opposed to the first electrode over and electrically connected to the other of the source and the drain in the memory transistor, a third electrode on both sidewalls of the second electrode other than an under portion of the second electrode, and a ferroelectric film between the first electrode and the two electrodes, the second electrode and the third electrode, wherein the ferroelectric capacitor comprises the first and the third electrode, and the ferroelectric film.

Further, another aspect of the invention, there is provided a semiconductor memory device, including, a TC unit series type FeRAM in which a plurality of memory cells, each of the memory cells comprising a memory transistor and a ferroelectric capacitor connected each other in parallel, are serially connected, comprising;

a first electrode over and electrically connected to one of a source and a drain in the memory transistor;

a ferroelectric film on at least both sidewalls of the first electrode along a bit line direction;

a second electrode opposed to the first electrode over and electrically connected the other of the source and the drain in the memory transistor, and embedded in a contact opening formed in the ferroelectric film; and

wherein the ferroelectric capacitor comprises the first electrode, the second electrode, the ferroelectric film and the contact opening sifting one pitch to the bit line direction in the adjacent memory cells.

Further, another aspect of the invention, there is provided a method for fabricating a semiconductor memory device, including, the method for fabricating a TC unit series type FeRAM in which a plurality of memory cells, each of the memory cells having a memory transistor and a ferroelectric capacitor connected each other in parallel, are serially connected, including forming the memory transistor over a semiconductor substrate, the memory transistor being surrounded by an element isolation region, the memory transistor including a channel region being sandwiched between a source and a drain region and a gate insulator and a gate electrode film formed to be stacked in layer on the channel region, forming a first inter-layer insulator on the memory transistor, selectively removing the first inter-layer insulator to form a first opening on the source and the drain, embedding a first conductive film in the first opening to form a plug, the plug connecting to the source and the drain, forming a second inter-layer insulator on the first inter-layer insulator and the plug, selectively removing the second inter-layer insulator to form a second opening on the plug, embedding a second conductive film in the second opening to form a via electrode, forming a first diffusion barrier film on the second inter-layer insulator and the via electrode, forming a third inter-layer insulator on the first diffusion barrier film, selectively removing the third inter-layer insulator and the first diffusion barrier film to form a third opening on the via electrode formed over one of the source and the drain, embedding a third conductive film in the third opening to form a first electrode, selectively removing the third inter-layer insulator and the first electrode to expose a surface of the first diffusion barrier film, selectively removing the first electrode and the first diffusion barrier film to form a fourth opening on the via electrode formed over the other of the source and the drain, forming a ferroelectric film over the semiconductor substrate, forming a second electrode on the ferroelectric film, selectively removing the second electrode to leave a sidewall of the second electrode, forming a fifth opening on the via electrode formed over the other of the source and the drain in the transistor, and embedding a fourth conductive film in the fifth opening to form a third electrode.

### BRIEF DESCRIPTION OF THE DRAWINGS

FIG. 1 is a circuit diagram showing a ferroelectric memory device according to a first embodiment of the present invention;

FIG. 2 is a top view showing the ferroelectric memory device according to the first embodiment of the present invention;

FIG. 3 is a cross-sectional view along A-A line in FIG. 2 showing the ferroelectric memory device according to the first embodiment of the present invention;

FIG. 4 is a cross-sectional view along B-B line in FIG. 2 showing the ferroelectric memory device according to the first embodiment of the present invention;

FIGS. 5A and 5B are cross-sectional views showing a processing step in fabricating the ferroelectric memory device according to the first embodiment of the present invention;

FIGS. 6A and 6B are cross-sectional views showing the processing step in fabricating the ferroelectric memory device according to the first embodiment of the present invention;

FIGS. 7A and 7B are cross-sectional views showing the processing step in fabricating the ferroelectric memory device according to the first embodiment of the present invention;

FIGS. 8A and 8B are cross-sectional views showing the processing step in fabricating the ferroelectric memory device according to the first embodiment of the present invention;

FIGS. 9A and 9B are cross-sectional views showing the processing step in fabricating the ferroelectric memory device according to the first embodiment of the present invention;

FIGS. 10A and 10B are cross-sectional views showing the processing step in fabricating the ferroelectric memory device according to the first embodiment of the present invention;

FIGS. 11A and 11B are cross-sectional views showing the processing step in fabricating the ferroelectric memory device according to the first embodiment of the present invention;

FIGS. 12A and 12B are cross-sectional views showing the processing step in fabricating the ferroelectric memory device according to the first embodiment of the present invention;

FIG. 13 is a cross-sectional view showing a ferroelectric memory device as a comparative example according to the first embodiment of the present invention;

FIG. 14 is a cross-sectional view showing a processing step in fabricating the ferroelectric memory device as the comparative example according to the first embodiment of the present invention;

FIG. 15 is a cross-sectional view showing the processing step in fabricating the ferroelectric memory device as the comparative example according to the first embodiment of the present invention;

FIG. 16 is a diagram showing a film thickness variation of a ferroelectric film in the ferroelectric memory device as the comparative example according to the first embodiment of the present invention;

FIG. 17 is a cross-sectional view showing a ferroelectric memory device according to a second embodiment of the present invention;

### DETAILED DESCRIPTION OF THE INVENTION

Embodiments of the present invention will be described below in detail with reference to the drawing mentioned above.

### First Embodiment

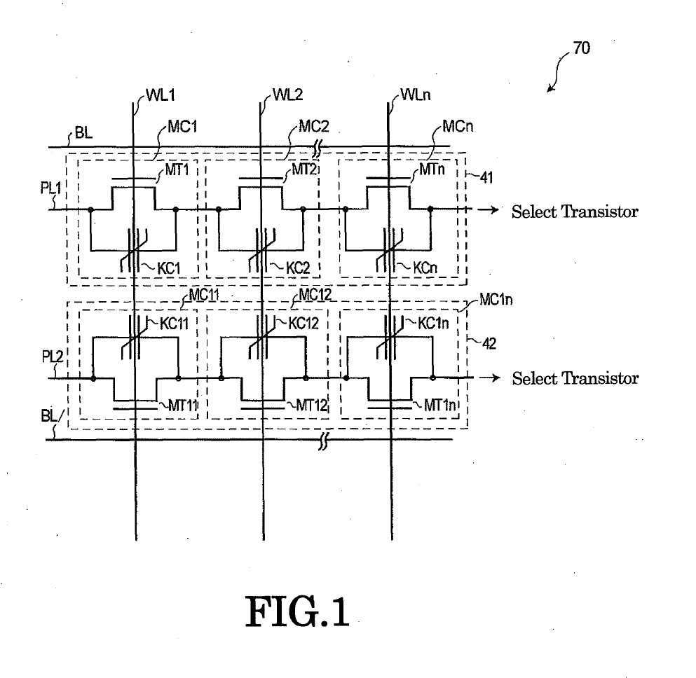

First, a semiconductor memory device according to a first embodiment of the present invention will be described below in detail with reference to FIGS. 1-4.

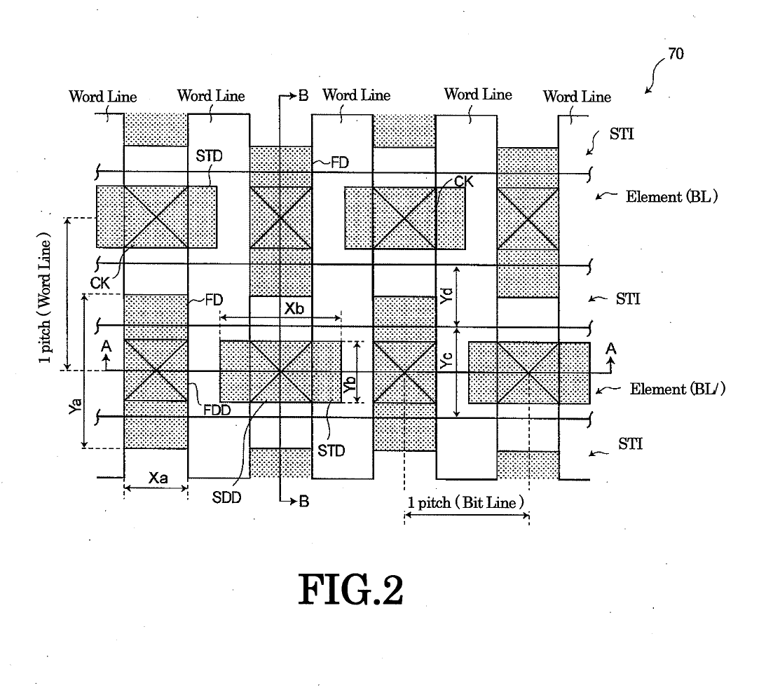

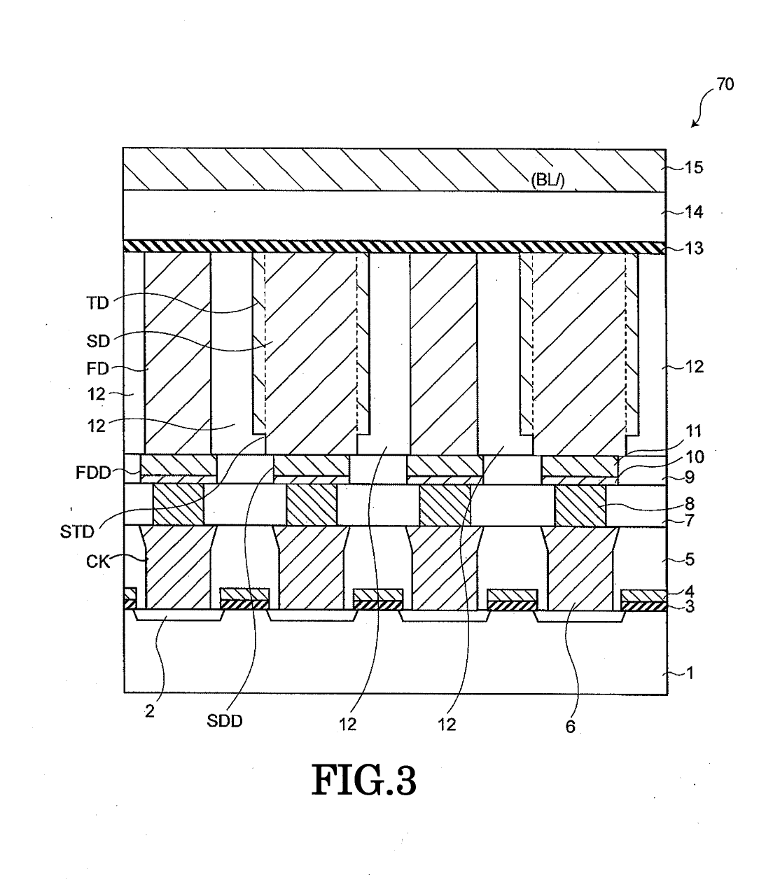

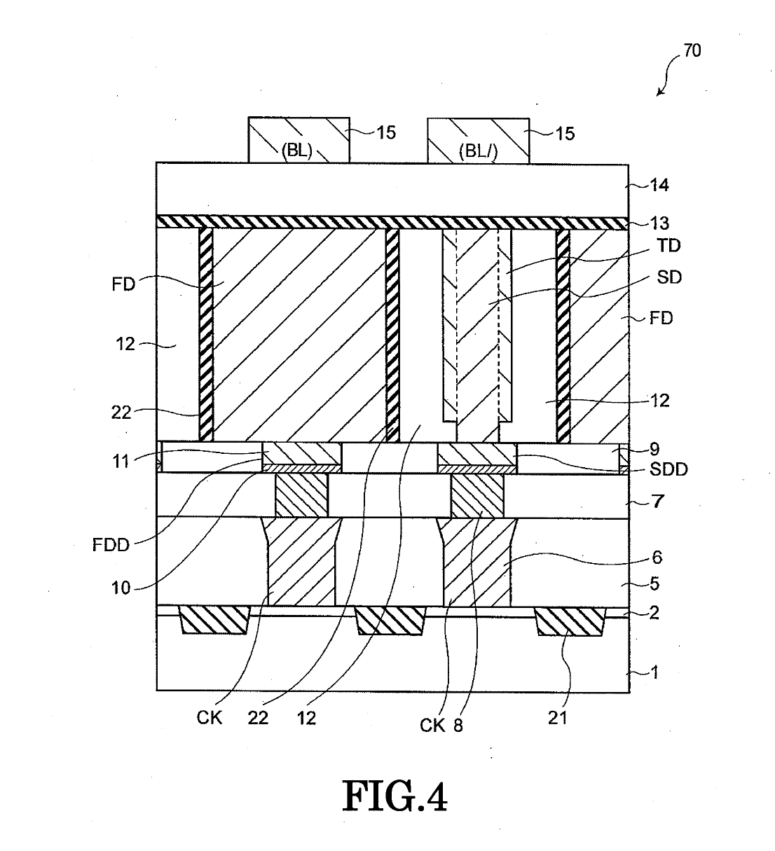

FIG. 1 is a circuit diagram showing a ferroelectric memory device. FIG. 2 is a top view showing the ferroelectric memory device. FIG. 3 is a cross-sectional view along A-A line in FIG. 2 showing the ferroelectric memory device. FIG. 4 is a cross-sectional view along B-B in FIG. 2 line showing the ferroelectric memory device.

A structure of a ferroelectric memory device is newly proposed for decreasing a variation in a thickness of the ferroelectric film in this embodiment. The new ferroelectric memory device is a TC unit series type FeRAM serially connected with memory cells having a memory transistor and a ferroelectric capacitor connected in parallel.

As shown in FIG. 1, a plurality of memory cells, each of the memory cells having a memory transistor and a ferroelectric capacitor connected each other in parallel are serially connected in a ferroelectric memory 70. The ferroelectric memory 70 is a TC unit series-type FeRAM. Here, drawings and explanations of a word line selection circuit, a sense amplifier or the like are omitted.

A memory cell portion 41 is configured in parallel with a bit line BL between a plate line PL1 and a selection transistor (not shown). In the memory cell portion 41, a plurality of memory cells MC1, MC2, . . . and MCn are serially configured. In detail, the memory cell MC1 has a memory transistor MT1 and a ferroelectric capacitor KC1 which are connected in parallel; the memory cell MC2 has a memory transistor MT2 and a ferroelectric capacitor KC2 which are connected in parallel, . . . and the memory cell MCn has a memory transistor MTn and a ferroelectric capacitor KCn which are connected in parallel. The memory cell portion 41 is connected to the bit line BL and a sense amplifier (not shown) via a selection transistor.

A memory cell portion 42 is configured in parallel with a bit line BL/ between a plate line PL2 and a selection transistor (not shown). In the memory cell portion 42, a plurality of memory cells MC11, MC12, . . . and MC1n are serially configured. In detail, the memory cell MC11 has a memory transistor MT11 and a ferroelectric capacitor KC11 which are connected in parallel; the memory cell MC12 has a memory transistor MT12 and a ferroelectric capacitor KC12 which are connected in parallel, . . . and the memory cell MC1n has a memory transistor MT1n and a ferroelectric capacitor KC1n which are connected in parallel. The memory cell portion 42 is connected to a bit line BL/ and the sense amplifier (not shown) via the selection transistor.

A word line WL1 is connected to gates of the memory transistor MT1 and the memory transistor MT11 and is configured to be crossed with the bit line BL and the bit line BL/. A word line WL2 is connected to gates of the memory transistor MT2 and the memory transistor MT12 and is configured to be crossed with the bit line BL and the bit line BL/. A word line WLn is connected to gates of the memory transistor MTn and the memory transistor MT1n and is configured to be crossed with the bit line BL and the bit line BL/.

As shown in FIG. 2, an element region having a longitudinal direction size Yc isolated by a shallow trench isolation (STI) region having a longitudinal direction size Yd is configured in the ferroelectric memory 70. A contact openings CK having a lateral direction size Xa and a longitudinal direction size Yb are configured in an element region (bit line BL) and an element region (bit line BL/), respectively. An electrode FD which is a first electrode electrically connected to one of a source and a drain in the memory transistor and an electrode STD electrically connected to the other of a source and a drain in the memory transistor are configured with sifting mutually one pitch to a bit line direction on each of the contact opening CK. A constitution of the electrode STD is mentioned below.

The contact opening CK is configured on the source or the drain of the memory transistor between the two word lines. An electrode FD which is a first electrode electrically connected to one of a source and a drain in the memory transistor and an electrode STD electrically connected to the other of a source and a drain in the memory transistor are configured with sifting mutually one pitch to a bit line direction on the contact opening CK.

A pedestal electrode FDD which is a first pedestal electrode is configured under the electrode FD which is the first electrode and a pedestal electrode SDD which is a second pedestal electrode is configured under the electrode STD. The pedestal electrode FDD and the pedestal electrode SDD have a lateral direction size Xa and a longitudinal direction size Yb, respectively, and are configured on the same position as the contact openings CK.

The electrode FD which is the first electrode has a lateral direction size Xa and a longitudinal direction size Ya. The size of longitudinal direction Ya is larger than the lateral direction size Xa. The electrode STD has a lateral direction size Xb and a longitudinal direction size Yb. The lateral direction size Xb is larger than the longitudinal direction size Yb. The electrode FD and the electrode STD are configured as like a checkered pattern. The ferroelectric capacitor is constituted with the electrode FD which is the first electrode, the electrode STD, and the ferroelectric film. The ferroelectric capacitor is mentioned in detail below.

As shown in FIG. 3, a source/drain region 2 of the memory transistor having the reverse conductive type to a semiconductor substrate 1 in the ferroelectric memory 70 is configured on the semiconductor substrate 1. A gate electrode film 4 is selectively configured on a portion between the source/drain region 2 to overlap with the source/drain region 2 via a gate insulator 3. An inter-layer insulator 5 is configured to cover the source/drain region 2, the gate insulator 3 and the gate electrode film 4.

The contact opening CK is configured to expose a portion of the source/drain region 2 in the inter-layer insulator 5. A plug 6 is embedded in the contact opening CK. A via 8 is embedded in an opening on the plug 6, the opening being opened in an inter-layer insulator 9. A barrier film and a metal film 11 which are stacked in layer and constitute the pedestal electrode SDD and the pedestal electrode FDD are embedded in openings formed on the via 8. The pedestal electrode SDD and the pedestal electrode FDD are the second pedestal electrode and the first pedestal electrode, respectively. The opening is opened in the inter-layer insulator 9.

The electrode FD which is the first electrode having a square prism shape and a sidewall of the electrode FD which contacts with a ferroelectric film 12 is configured on the pedestal electrode FDD being the first pedestal electrode. An electrode SD which is a second pedestal electrode having a square prism shape is configured on the pedestal electrode SDD. A third electrode which is an electrode TD is configured on both sidewalls other than an under portion of the side wall on the second electrode being the electrode SD. The electrode STD is constituted with the electrode SD and the electrode TD. The ferroelectric film 12 is configured between the electrode FD which is the first electrode and the electrode STD.

A diffusion barrier layer 13 and an inter-layer insulator 14 is stacked in layer on the electrode FD, the electrode SD, the electrode TD and the ferroelectric film 12. An interconnection layer 15 being the bit line BL/ is configured on the inter-layer insulator 14.

As shown in FIG. 4, the source/drain region 2 which is separated by the STI 21 in the ferroelectric memory 70 is configured on the semiconductor substrate 1. The contact opening CK is configured to expose a portion of the source/drain region 2 on the inter-layer insulator 5 and the contact opening CK is filled with the plug 6. The via 8 is embedded in an opening on the plug 6, the opening being opened in the inter-layer insulator 7. The barrier film and the metal film 11 being stacked in layer and constituting the pedestal electrode SDD which is the second pedestal electrode and the pedestal electrode FDD which is the first pedestal electrode are embedded in openings on the via 8, the openings being opened in the inter-layer insulator 9.

The electrode FD which is the first electrode having a square prism shape and is wider than that of the pedestal electrode FDD is configured on the pedestal electrode FDD being the first pedestal electrode. A sidewall of the electrode FD is contacted with a diffusion barrier layer 22. The electrode SD which is the second pedestal electrode having a square prism shape and is narrower than that of the pedestal electrode FDD is configured on the pedestal electrode SDD. The third electrode being an electrode TD is configured on both sidewalls other than an under portion of a side-wall of the second electrode being the electrode SD. The electrode STD is constituted with the electrode SD and the electrode TD. The ferroelectric film 12 is configured between the diffusion barrier layer and the electrode STD.

The diffusion barrier layer 13 and the inter-layer insulator 14 is stacked in layer on the electrode FD, the electrode SD, the electrode TD and the ferroelectric film 12. The interconnection layers 15 which are the bit line BL and the bit line BL/ are configured on the inter-layer insulator 14. The diffusion barrier layer 13 and the diffusion barrier layer 22 act as preventing elements constituting the ferroelectric film 12 from out-diffusion.

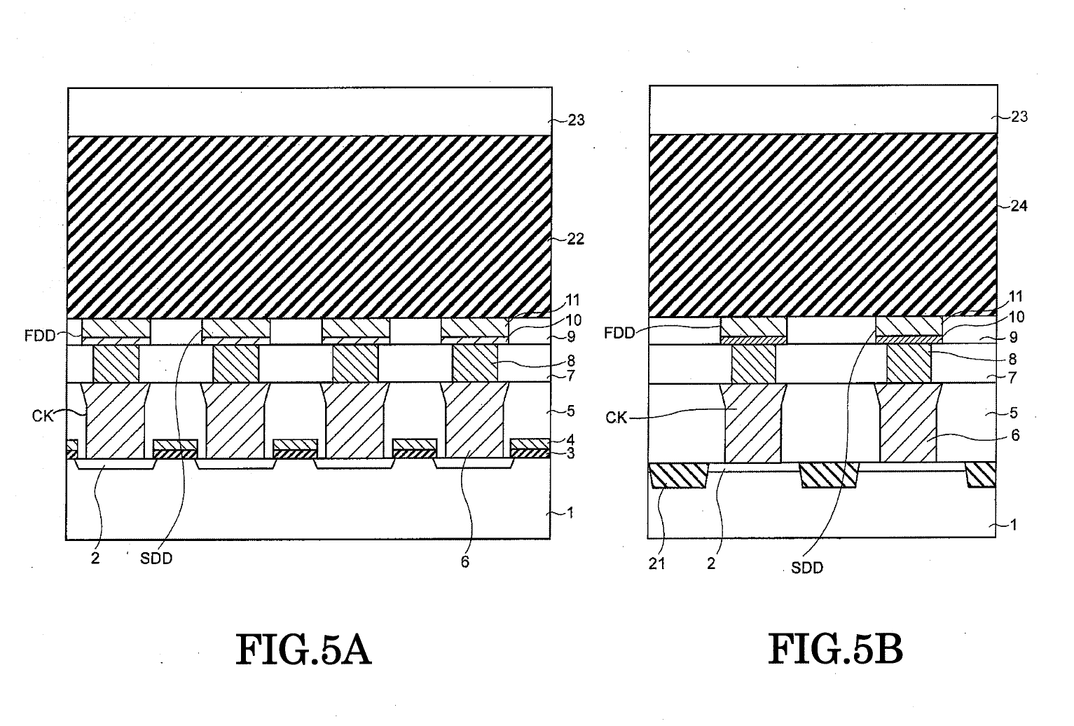

Next, processing steps in fabricating the ferroelectric memory device according to the first embodiment of the present invention will be described below in detail with reference to FIGS. 5-12 which are cross-sectional views showing the processing steps in fabricating the ferroelectric memory device. Here, FIGS. 5A-12A are cross-sectional views along A-A line in FIG. 2 showing the ferroelectric memory device according to the first embodiment of the present invention and FIGS. 5B-12B are cross-sectional views along B-B line in FIG. 2 showing the ferroelectric memory device according to the first embodiment of the present invention.

As shown in FIG. 5, the STI 21 is formed in the semiconductor substrate 1. The gate insulator 3 and the gate electrode film 4 are selectively stacked in layer to be formed on the semiconductor substrate 1 between the STIs 21. The source/drain region is formed to sandwich the semiconductor substrate 1 beneath the gate insulator 3 and the gate electrode film 4 stacked in layer and to overlap with the gate insulator 3. The inter-layer insulator 5 is formed over the source/drain region, the gate insulator 3 and the gate electrode film 4. The inter-layer insulator 5 formed on the source/drain region 2 is etched to be opened openings being the contact openings CK. The plug 6 is embedded in the contact opening CK which exposes a portion of the source/drain region 2. Here, a highly impurity-doped poly-silicon is used as the plug. However, tungsten (W), tantalum (Ta), titanium (Ti), nickel (Ni) or the like may be used instead of the highly impurity-doped polycrystalline silicon.

The inter-layer insulator 7 is formed on the plug 6 and inter-layer insulator 5. The via 8 is embedded in an opening opened in the inter-layer insulator 7. The inter-layer insulator 9 is formed in the via 8 and the inter-layer insulator 7. The pedestal electrode FDD and the pedestal electrode SDD which are constituted with the barrier film 10 and the metal film 11 stacked in layer are embedded in an opening opened in the inter-layer insulator 9. The diffusion barrier film 22 and an insulator 23 are stacked in layer on the metal film 11 and the inter-layer insulator 9.

Here, titanium aluminum nitride (TiAlN) is used as the barrier film 10. However, titanium nitride iridium (TiNIr), tantalum silicon nitride (TaSiN), titanium silicon nitride (TiSiN) or the like may be used instead of TiAlN. Iridium (Ir) is used as the metal film 11. However, ruthenium (Ru), strontium ruthenium oxide (SrRuOₓ), ruthenium oxide (RuOₓ) or the like may be used instead of Ir. Aluminum oxide (Al₂O₃) is used as the diffusion barrier film 22. However, silicon nitride film (SiN) or the like may be used instead of Al₂O₃.

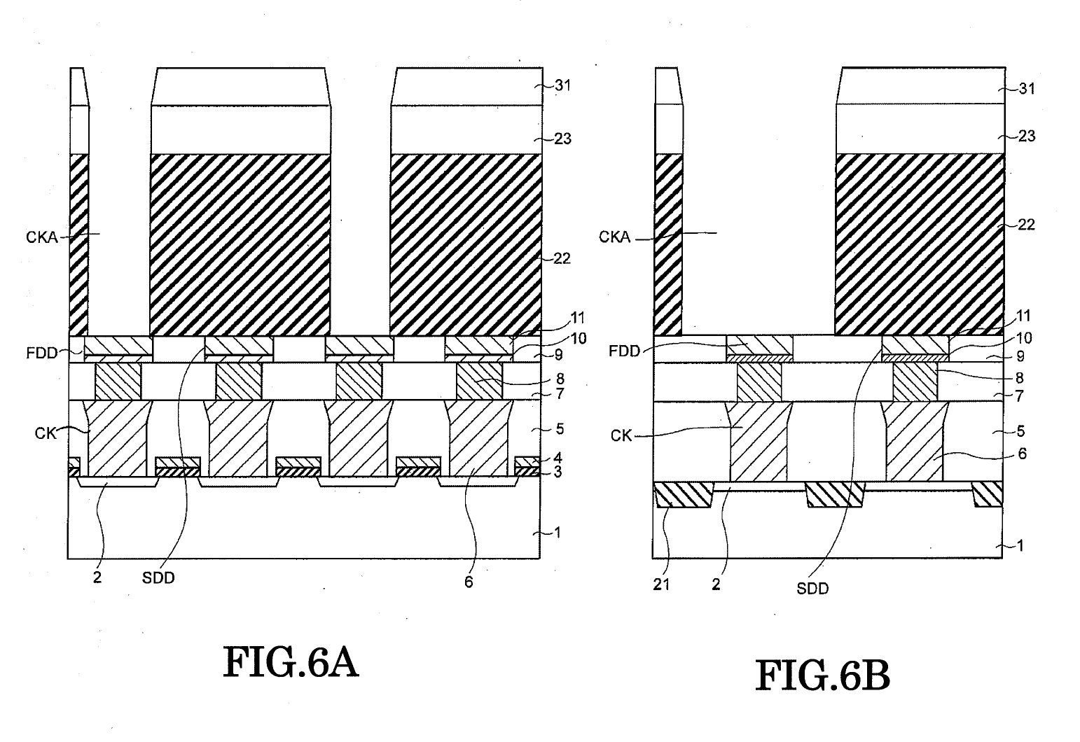

As shown in FIG. 6, a resist film 31 is formed on the insulator 23 by well-known lithography technique. The insulator 23 and the diffusion barrier film 22 are etched, for example, by reactive ion etching (RIE) using the resist film 31 as a mask so that a contact opening CKA are formed on the pedestal electrode FDD being the first pedestal electrode.

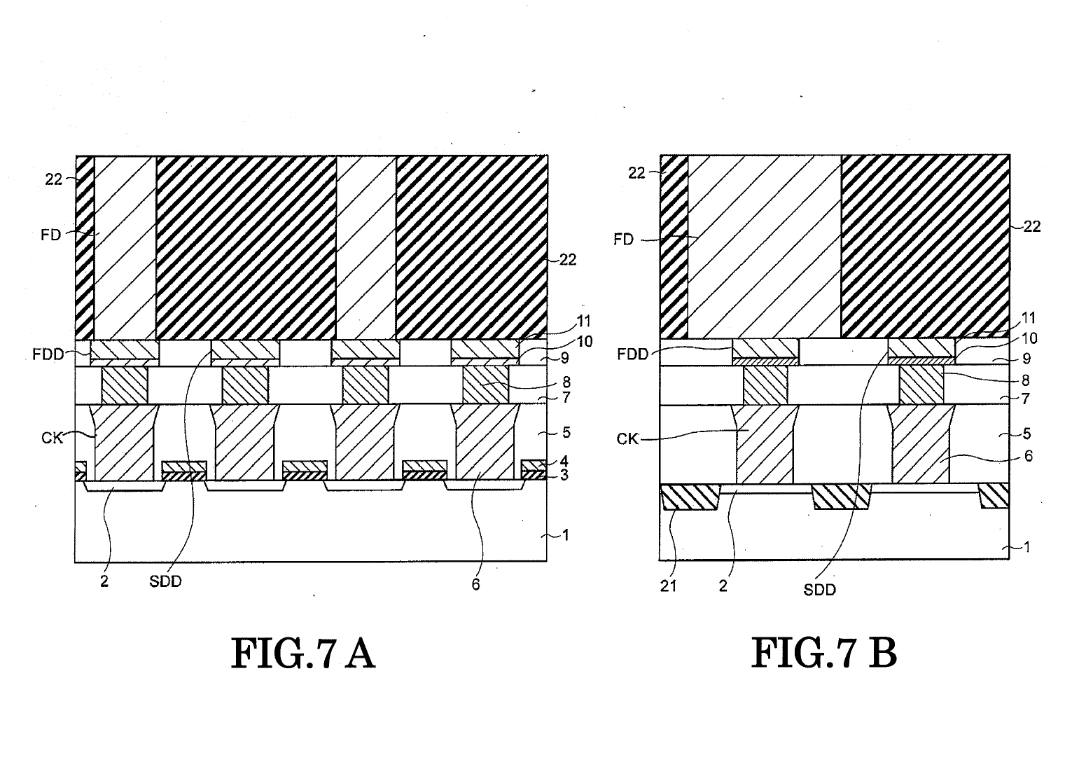

As shown in FIG. 7, after removing the resist film 31, the electrode FD which is the first electrode is deposited to be embedded in the contact opening CKA, for example, by CVD. After depositing the electrode FD, the electrode FD being the first electrode and the insulator 23 are polished to be flattened, for example, by chemical mechanical polishing (CMP) till a surface of the diffusion barrier film 22. Here, Ir is used as the electrode FD being the first electrode.

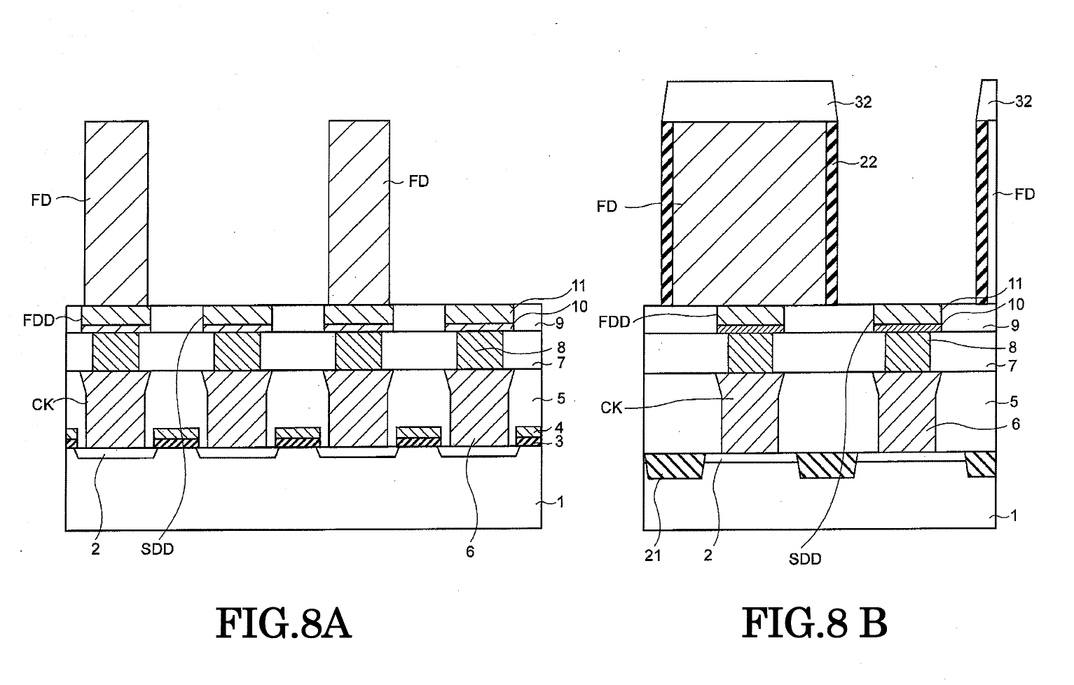

As shown in FIG. 8, a resist film 32 is formed on the electrode FD being the first electrode and the diffusion barrier layer 22 along the word line direction by well-known lithography technique. The diffusion barrier film 22 is etched, for example, by RIE using the resist film 32. A portion of the diffusion barrier layer 22 surrounding the electrode FD being the first electrode is removed by the RIE.

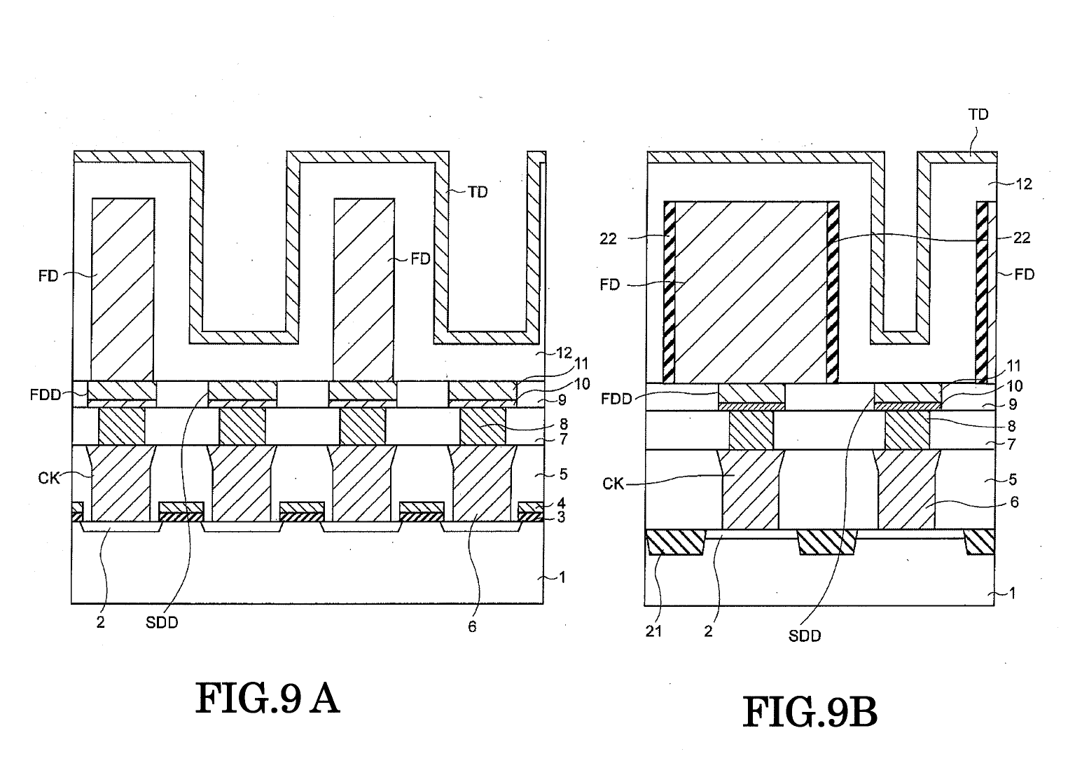

As shown in FIG. 9, after removing resist film 32, the ferroelectric film 12 and the electrode TD being the third electrode are successively formed. The ferroelectric film 12 is formed by metal organic chemical vapor deposition (MOCVD), for example, and the electrode TD being the third electrode is formed by CVD, for example.

Here, PbZrTiO₃ (PZT) is used as the ferroelectric film 12. However, SrBi₂Ta₂O₉ (SBT), (Bi, La)₄Ti₃O₁₂ (BLT), BaTi₂O₅ or the like may be used instead of PZT. Ir is used as the electrode TD being the third electrode.

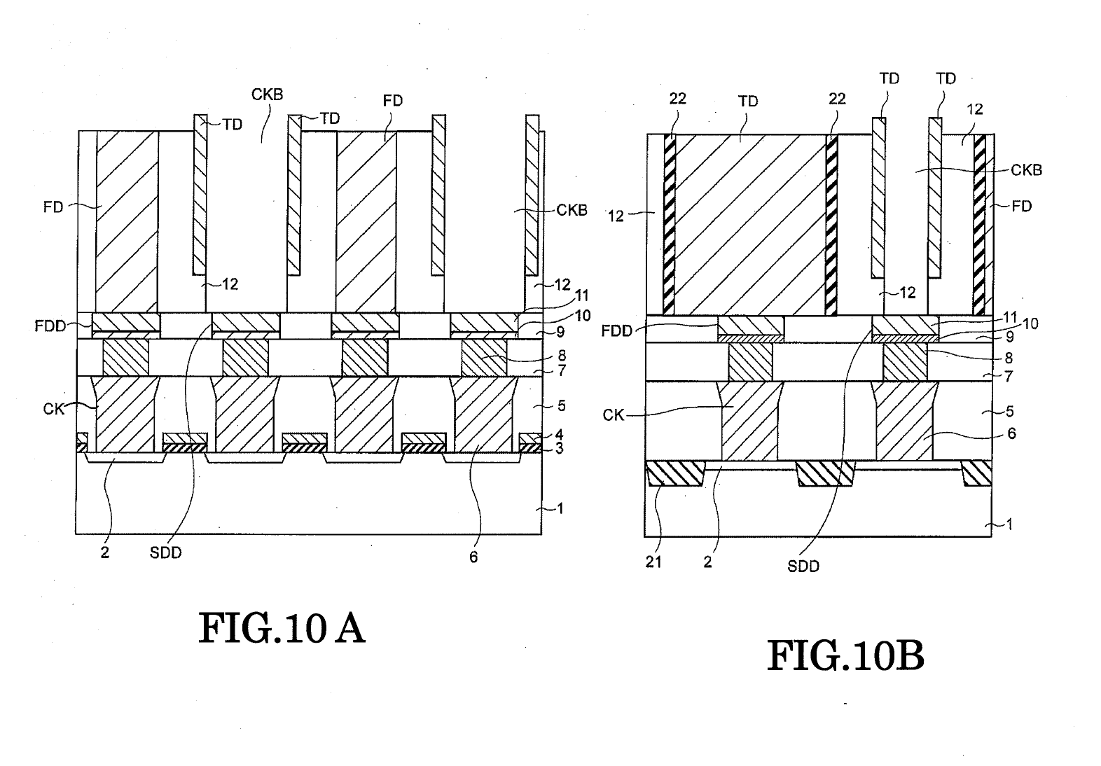

As shown in FIG. 10, Ir is totally back-etched by RIE, for example. A portion of Ir formed on a sidewall of the ferroelectric film 12 is left so that the portion of Ir formed on the sidewall becomes the electrode TD being the third electrode. In the back-etching process of Ir, using a larger etching ratio of PZT to Ir may be favorable as the RIE condition.

After leaving the portion of Ir formed on the sidewall, PZT is back-etched by RIE, for example, till an upper surface of the electrode pedestal SDD being the second electrode pedestal and an upper surface of the electrode FD of the first electrode are exposed. In the back-etching process of PZT, using a larger etching ratio of PZT to Ir may be favorable as a RIE condition.

As a result, contact openings CKB are formed on the upper surface of the electrode pedestal SDD being the second electrode pedestal. The electrode TD being the third electrode is formed on the sidewall of the contact openings CKB.

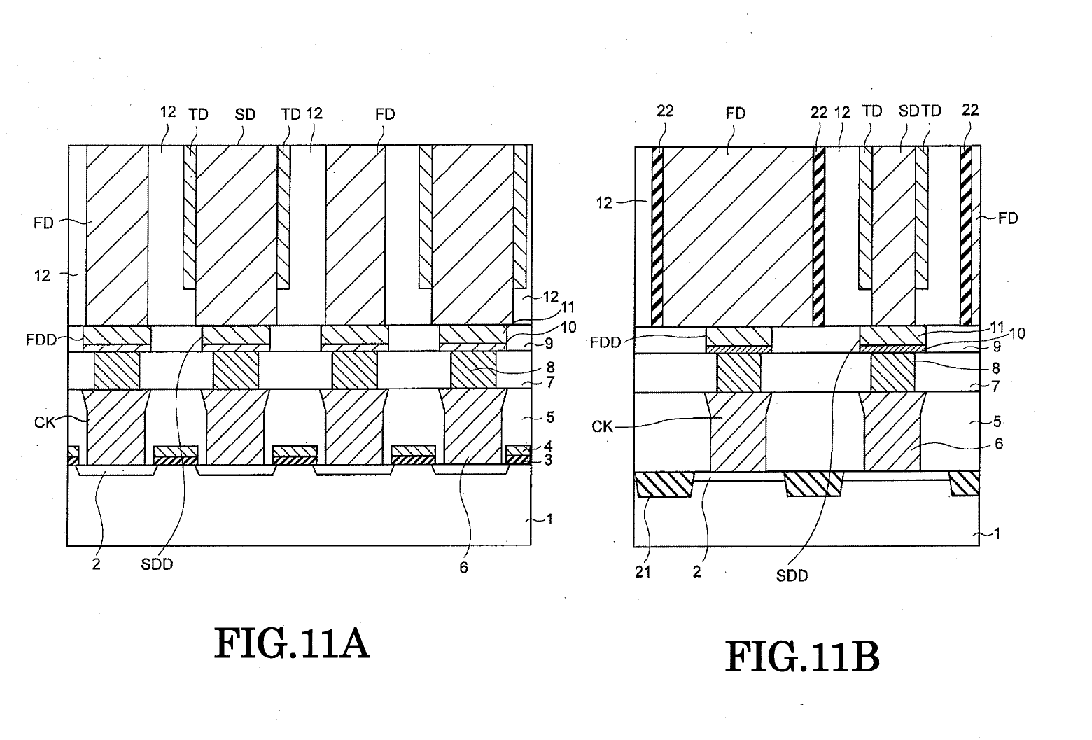

As shown in FIG. 11, the second electrode SD is deposited to be embedded in the contact opening CKB using CVD, for example. After being deposited, using chemical mechanical polishing (CMP), for example, the electrode SD which is the second electrode and the electrode TD which is the third electrode are polished to be flattened till a surface of the first electrode FD is exposed. Here, Ir is used as the second electrode SD.

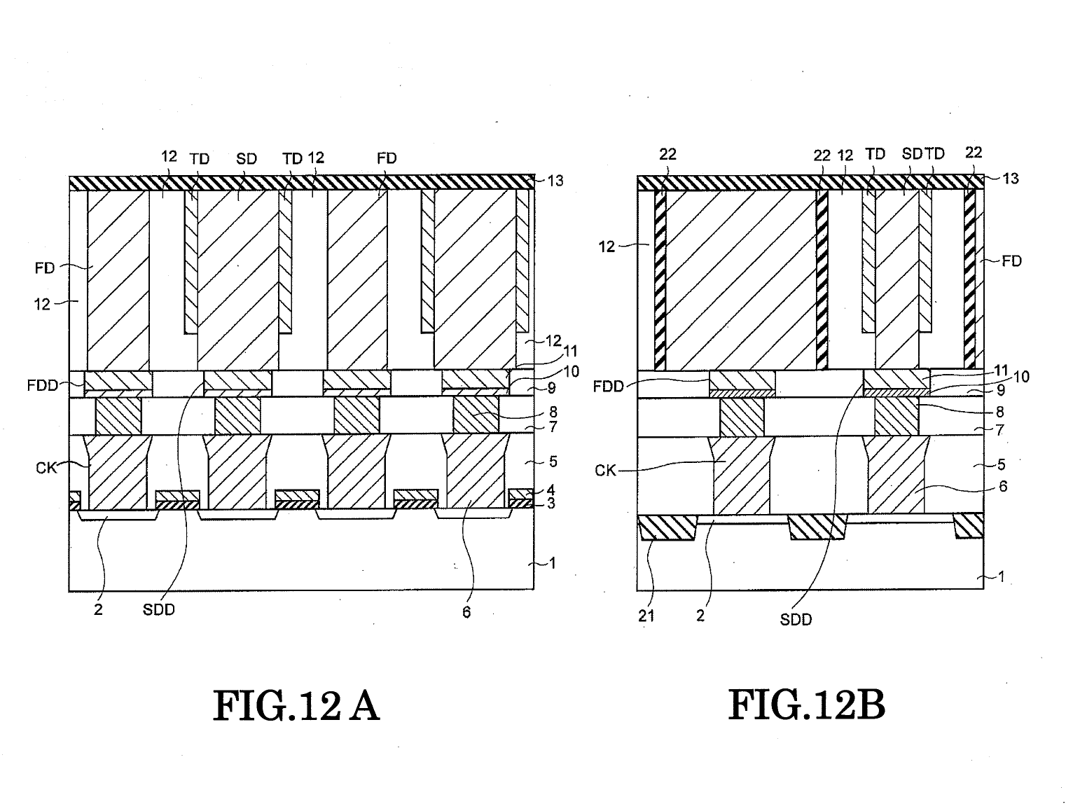

As shown in FIG. 12, the diffusion barrier film 13 is formed on the first electrode FD, the electrode SD being the second electrode, the electrode TD being the third electrode and the ferroelectric film 12. Here, an Al₂O₃ film is used as the diffusion barrier film 13. However, a SiN film may be used instead of the Al₂O₃ film. Here, Al₂O₃ constituting the diffusion barrier films 13 and 22 has a function to suppress an outer diffusion of Pb and O₂ contained in the PZT film constituting the ferroelectric film 12. Al₂O₃ has relative dielectric constant of 6-10, and is a dielectric material having low permittivity as compared to PZT or the like which is the ferroelectric film.

After forming the inter-layer insulator 14 and the interconnection layer 15, an inter-layer insulator, an interconnection layer or the like is formed by using well-known technique to complete the ferroelectric memory 70 as a chain FeRAM.

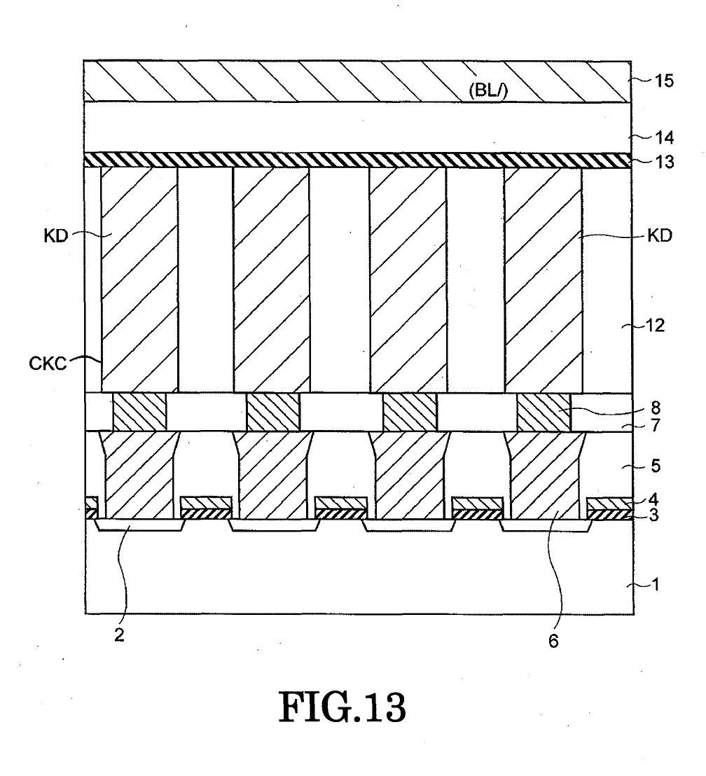

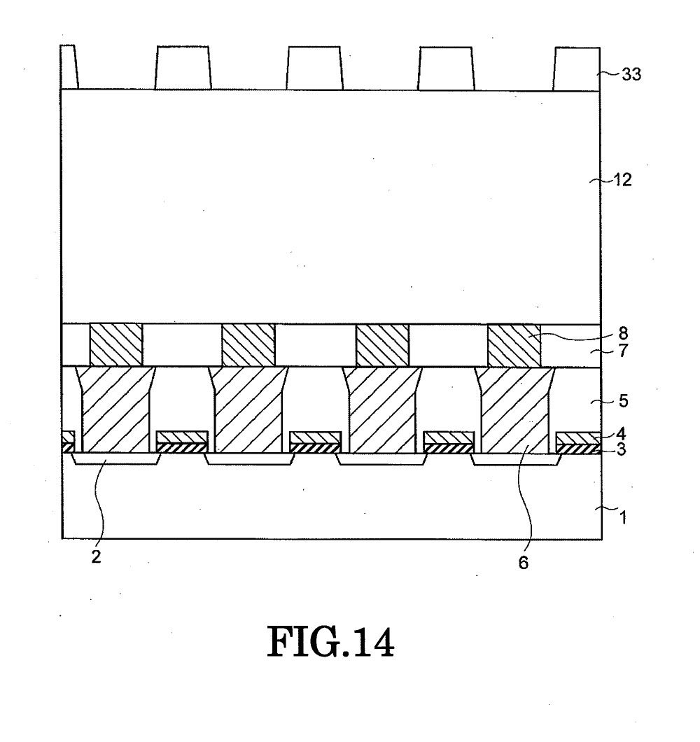

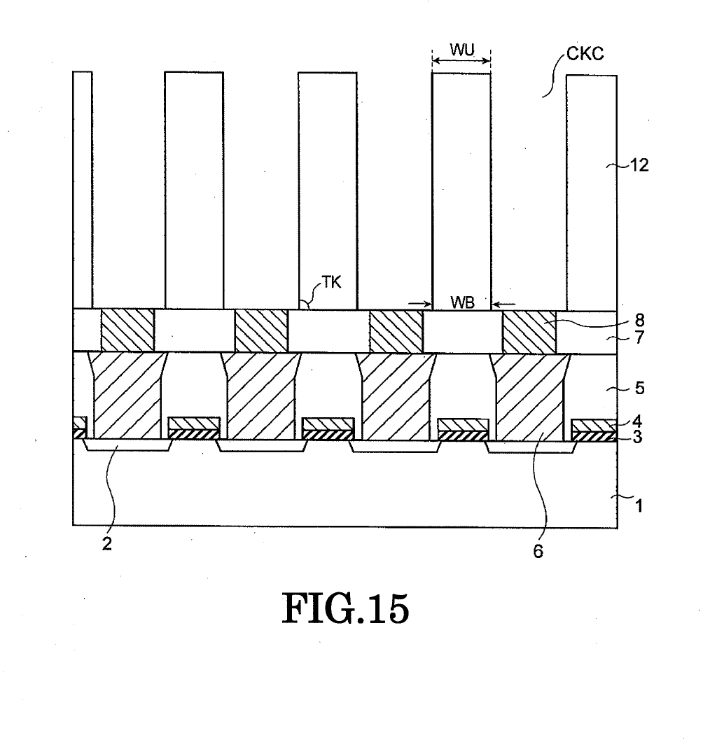

Next, a ferroelectric memory device as a comparative example and processing steps in fabricating the ferroelectric memory device as the comparative example according to the first embodiment will be described below in detail with reference to FIGS. 13-15. FIG. 13 is a cross-sectional view showing the ferroelectric memory device as the comparative example. FIG. 14 and FIG. 15 are cross-sectional views showing processing steps in fabricating the ferroelectric memory device as the comparative example. Different points between the comparative example and the first embodiment are explained on the ferroelectric memory device as the comparative example.

As shown in FIG. 13, an electrode KD is embedded in contact openings CKC which are opened in the dielectric film 12 formed on the via 8 in a ferroelectric memory 80 as the comparative example. The electrode KD configured on a source of a memory transistor has the same shape as the electrode KD formed on a drain of the memory transistor in the ferroelectric memory 80 as the comparative example. A ferroelectric capacitor in the ferroelectric memory 80 as the comparative example is constituted with the electrode KD formed on the source of the memory transistor, the ferroelectric film 12 and the electrode KD formed on the drain of the memory transistor.

As shown in FIG. 14, in forming the ferroelectric capacitor in the ferroelectric memory 80 as the comparative example, the ferroelectric film 12 is formed on the via 8 and the inter-layer insulator 7. Successively, a resist film 33 is formed by well known lithograph technique.

As shown in FIG. 15, using the resist film 33 as a mask, the contact openings CKC are formed on the via 8 by etching the ferroelectric film 12, for example, using RIE. After removing the resist film 33, the electrodes KD are formed to cover the contact openings CKC and are polished to be flatten by CMP, for example, till a surface of the ferroelectric film 12 is exposed.

When the contact openings CKC are formed by RIE, variation in shape of the contact openings CKC is generated. The variation totally includes, for example, variations in a size and a shape, a variation of a selective ratio between the resist film and a film being etched, a variation of a sidewall film deposited in the RIE process, a variation of an etching speed due to difference of an opening size, which is called a loading effect, or the like.

Accordingly, an under portion size WB in the ferroelectric film being an under portion size in the ferroelectric film 12 as a square prism shape is different from an upper portion size WU in the ferroelectric film being an upper portion size in the ferroelectric film 12 as a square prism shape so that a taper angle TK is sifted from 90 degree to be tapered. Consequently, the size of the ferroelectric film 12 in longitudinal direction becomes larger than the variation of the size of the resist film 33 and the variation of the film thickness formed by MOCVD or CVD.

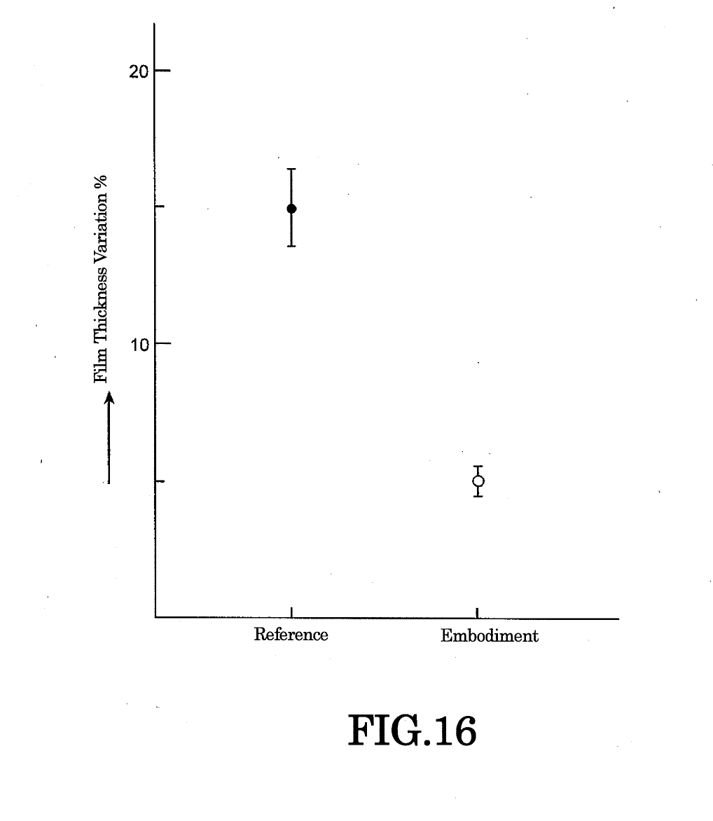

Next, the film thickness variation of the ferroelectric memory device as the comparative example will be described below in detail with reference to FIG. 16 which is a diagram showing a film thickness variation of the ferroelectric memory device as the comparative example.

As shown in FIG. 16, in the ferroelectric capacitor of this embodiment, the ferroelectric film 12 by MOCVD and the electrode TD being the third electrode by CVD are successively formed on the both sidewalls of the electrode FD being the first electrode. The electrode TD which is the third electrode and is formed on the both sidewalls of the ferroelectric film 12 protects the ferroelectric film 12 in subsequent processing steps. Therefore, the variation in the film thickness of the ferroelectric film 12 which is in parallel to the memory transistor is not added other than the variation in CVD. Consequently, an average of the variation in the film thickness of the ferroelectric film 12 which is in parallel to the memory transistor can be suppressed between ±5 percents.

On the other hand, in the ferroelectric capacitor as the comparative example, the ferroelectric film 12 is etched by RIE using the resist as the mask. As a result, the average of the variation in the film thickness of the ferroelectric film is ±15% due to the variation in the resist film or the variation in RIE is larger than that of the first embodiment. Further, a fluctuating range of the variation in the comparative example is larger than that in the first embodiment.

Further, the ferroelectric film 12 is etched by using resist film as the mask in the ferroelectric capacitor of the comparative example. However, processing steps as another case are also available as the fabricating method. For example, the insulator is processed by RIE using the resist film as the mask and the electrode is embedded in the opening. The ferroelectric film is embedded in a groove portion which is removed the insulator. For another method, the electrode film is processed by RIE using the resist film as the mask and the ferroelectric film is embedded in the opening. As similarly with the examples mentioned above, the film thickness variation in parallel with the memory transistor of the ferroelectric film 12 cannot be decreased.

As mentioned above, the plurality of memory cells having the memory transistor and the ferroelectric capacitor connected in parallel are serially connected in the semiconductor memory device in the first embodiment. The ferroelectric capacitor connected the memory transistor in parallel is formed on the memory transistor in parallel. The electrode FD is configured on the pedestal electrode FDD connected with one of the source and drain in the memory transistor and the sidewall of the electrode FD is connected with the ferroelectric film 12. The electrode SD is configured on the pedestal electrode SDD connected with the other of the source and drain in the memory transistor. The electrode TD is configured on both sidewalls of the electrode SD other than a lower portion of the sidewall. The electrode SD and the electrode TD is constituted with the electrode STD. The ferroelectric film 12 is configured between the electrode FD and the electrode STD. The ferroelectric film 12 is formed on the both sidewalls of the electrode SD by MOCVD. The electrode TD is formed on both sidewalls of the ferroelectric film 12 by CVD. The ferroelectric film 12 and the electrode TD are successively formed. The electrode FD, the ferroelectric film 12 and the electrode STD are constituted with the ferroelectric capacitor.

Therefore, a film thickness of the ferroelectric film 12 constituting the ferroelectric capacitor is determined by MOCVD and is independent on a processed shape. Accordingly, a variation in the film thickness of the ferroelectric film 12 can be markedly decreased as compared to forming the ferroelectric film 12 by using EIE. As the variation in the film thickness of the ferroelectric film 12 can be decreased, a variation in operation voltage and signal of the ferroelectric memory 70 can be decreased, so that an operation yield or reliability of the ferroelectric memory 70 can be improved.

Further, a size in the word line direction is set to be larger than a size in the bit line direction in the electrode FD and the size in the bit line direction is set to be larger than the size in the word line direction in the electrode STD in this embodiment. However, the shapes my not be restricted as the case mentioned above and may be arbitrarily changed. For example, the shape of the electrode FD can be formed as the same as the shape of the electrode STD from a point of top view.

### Second Embodiment

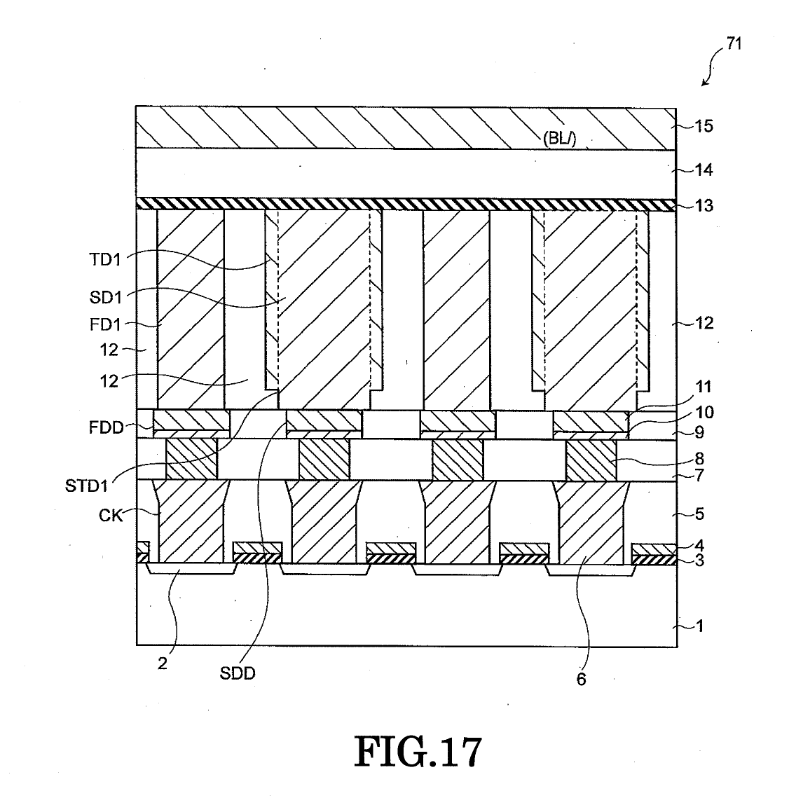

Next, a ferroelectric memory device according to a second embodiment will be described below in detail with reference to FIG. 17. FIG. 17 is a cross-sectional view showing the ferroelectric memory device according to the second embodiment. A structure of the ferroelectric capacitor in a chain FeRAM as the ferroelectric memory is modified in this embodiment.

It is to be noted that the same or similar reference numerals with the first embodiment are applied to the same or similar parts and elements throughout the drawings, and the description of the same or similar parts and elements will be omitted or simplified.

As shown in FIG. 17, an electrode FD1 which is the first electrode is configured on the pedestal electrode FDD which is the first pedestal electrode in a ferroelectric memory 71. A sidewall of the electrode FD1 is connected with the ferroelectric film 12 and has a square prism shape. An electrode SD1 which is the second electrode and has a square prism shape is configured on the pedestal electrode SDD which is the second pedestal electrode. An electrode TD1 which is the third electrode is configured on both sidewalls other than a lower portion of the electrode SD1 which is the second electrode. The electrode SD1 and the electrode TD1 are constituted with the electrode STD1. The ferroelectric film 12 is configured between the electrode FD1 being the first electrode and the electrode STD1.

Here, Ru is used as the electrode FD being the first electrode. However, SrRuOₓ, RuOₓ or the like may be used. Ru is used as the electrode FD2 being the second electrode. However, SrRuOₓ, RuOₓ or the like may be used. IrOₓ is used as the electrode TD being the third electrode. However, SrRuOₓ, RuOₓ, IrOₓ/Ir/IrOₓ laterally stacked or the like may be used.

As mentioned above, the plurality of memory cells having the memory transistor and the ferroelectric capacitor connected in parallel are serially connected in the semiconductor memory device in this embodiment. The ferroelectric capacitor connected the memory transistor in parallel is formed on the memory transistor in parallel. The electrode FD is configured on the pedestal electrode FDD connected with one of the source and drain in the memory transistor. The sidewall of the electrode FD is connected with the ferroelectric film 12. The electrode SD is configured on the pedestal electrode SDD connected with the other of the source and drain in the memory transistor. The electrode TD is configured on both sidewalls of the electrode SD other than the lower portion of the sidewall. The electrode SD and the electrode TD are constituted with the electrode STD. The ferroelectric film 12 is configured between the electrode FD and the electrode STD. The ferroelectric film 12 is formed on the both sidewalls of the electrode SD by MOCVD. The electrode TD is formed on both sidewalls of the ferroelectric film 12 by CVD. The ferroelectric film 12 and the electrode TD are successively formed. The electrode FD, the ferroelectric film 12 and the electrode STD are constituted with the ferroelectric capacitor. Ru is used as the electrode FD and the electrode FD2 and IrOₓ is used as the electrode TD.

Therefore, a film thickness of the ferroelectric film 12 constituting the ferroelectric capacitor is determined by MOCVD and is independent on a processed shape. Accordingly, the second embodiment has same effects as the first embodiment.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the claims that follow. The invention can be carried out by being variously modified within a range not deviated from the gist of the invention.

What is claimed is:

1. A semiconductor memory device, comprising:
a TC unit series-type ferroelectric random access memory (FeRAM) comprising a plurality of memory cells serially connected, each memory cell comprising a memory transistor and a ferroelectric capacitor being connected each other in parallel, comprising;
a first electrode over and electrically connected to one of a source and a drain in the memory transistor;
a second electrode opposite to the first electrode over and electrically connected to the other of the source and the drain in the memory transistor;
a third electrode on both sidewalls of the second electrode other than an under portion of the second electrode; and
a ferroelectric film between the first electrode and the two electrodes, the second electrode and the third electrode;
wherein the ferroelectric capacitor comprises the first electrode, the third electrode and the ferroelectric film.

2. The semiconductor memory device of claim 1, further comprising:
pedestal electrodes on a bottom surface of the first electrode and a bottom surface of the second electrode.

3. The semiconductor memory device of claim 1, further comprising:
a dielectric film on both sidewalls of the first electrode along a word line direction, permittivity of the dielectric film being lower than permittivity of the ferroelectric film, the dielectric film configured to prevent materials in the ferroelectric film from diffusing to an outer region.

4. The semiconductor memory device of claim 1, wherein
a size in the word line direction of the first electrode is larger than a size in a bit line direction of the first electrode and a size in the bit line direction of the second electrode is larger than a size in the word line direction of the second electrode.

5. The semiconductor memory device of claim 1, further comprising:
a diffusion barrier layer on upper surfaces of the first electrode, the second electrode, the third electrode and the ferroelectric film, the diffusion barrier layer configured to prevent materials in the ferroelectric film from diffusing to the outer region.

6. The semiconductor memory device of claim 1, wherein
the first electrode comprises one of iridium (Ir), ruthenium (Ru), strontium ruthenium oxide (SrRuO_{X}) and ruthenium oxide (RuO_{X}).

7. The semiconductor memory device of claim 1, wherein
the second electrode comprises one of Ir, iridium oxide (IrO_{X}), SrRuO_{X} and RuO_{X}.

8. The semiconductor memory device of claim 1, wherein
the third electrode comprises one of Ir, IrO_{X}, SrRuO_{X}, RuO_{X} and IrO_{X} and Ir laterally in layer in an order or IrOx, Ir, and IrOx.

9. The semiconductor memory device of claim 1, wherein
the diffusion barrier layer is aluminum oxide (Al₂O₃) or silicon nitride film (Si₃N₄).

10. The semiconductor memory device of claim 2, wherein
each pedestal electrode comprises a stacked structure comprising either titanium aluminum nitride (TiAlN) and Ir or titanium nitride iridium (TiNIr) and Ir.

11. The semiconductor memory device of claim 2, wherein
the ferroelectric film comprises one of lead zirconate titanate (PZT), SrBi₂Ta₂O₉ (SBT), (Bi,La)₄Ti₃O₁₂ (BLT), or BaTi₂O₅.

12. A semiconductor memory device, comprising:
a TC unit series type FeRAM comprising a plurality of memory cells serially connected, each memory cell comprising a memory transistor and a ferroelectric capacitor being connected each other in parallel, comprising;
a first electrode over and electrically connected to one of a source and a drain in the memory transistor;
a ferroelectric film on at least both sidewalls of the first electrode along a bit line direction;
a second electrode opposite to the first electrode over and electrically connected the other of the source and the drain in the memory transistor, and in a contact opening in the ferroelectric film;
wherein the ferroelectric capacitor comprises the first electrode, the second electrode, the ferroelectric film and the contact opening located one pitch to the bit line direction in the adjacent memory cells.

13. The semiconductor memory device of claim 12, further comprising:
a third electrode between the contact opening and the ferroelectric film, the contact opening being opened via the third electrode.

14. The semiconductor memory device of claim 12, further comprising:
pedestal electrodes on a bottom surface of the first electrode and a bottom surface of the second electrode.

15. The semiconductor memory device of claim 12, further comprising:
a dielectric film on both sidewalls of the first electrode along a word line direction, permittivity of the dielectric film being lower than permittivity of the ferroelectric film, the dielectric film configured to prevent materials in the ferroelectric film from diffusing to an outer region.

16. A method for fabricating a semiconductor memory device, comprising:
fabricating a TC unit series type FeRAM comprising a plurality of memory cells serially connected, each memory cell comprising a memory transistor and a ferroelectric capacitor connected each other in parallel, comprising;
forming the memory transistor over a semiconductor substrate, the memory transistor being surrounded by an element isolation region, the memory transistor comprising a channel region between a source and a drain, and a gate insulator and a gate electrode film in layer on the channel region;
forming a first inter-layer insulator on the memory transistor;
selectively removing the first inter-layer insulator in order to form a first opening on the source and the drain;
embedding a first conductive film in the first opening in order to form a plug, the plug configured to connect to the source and the drain;
forming a second inter-layer insulator on the first inter-layer insulator and the plug;
selectively removing the second inter-layer insulator in order to form a second opening on the plug;
embedding a second conductive film in the second opening in order to form a via electrode;
forming a first diffusion barrier film on the second inter-layer insulator and the via electrode;
forming a third inter-layer insulator on the first diffusion barrier film;
selectively removing the third inter-layer insulator and the first diffusion barrier film in order to form a third opening on the via electrode over one of the source and the drain;
embedding a third conductive film in the third opening in order to form a first electrode;
selectively removing the third inter-layer insulator and the first electrode in order to expose a surface of the first diffusion barrier film;
selectively removing the first electrode and the first diffusion barrier film in order to form a fourth opening on the via electrode over the other of the source and the drain;
forming a ferroelectric film over the semiconductor substrate;
forming a second electrode on the ferroelectric film;
selectively removing the second electrode in order to leave a sidewall of the second electrode;
forming a fifth opening on the via electrode over the other of the source and the drain in the transistor; and
embedding a fourth conductive film in the fifth opening in order to form a third electrode.

17. The method for fabricating the semiconductor memory device of claim 16, further comprising;
forming a fourth inter-layer insulator on the first inter-layer insulator and the via electrode after forming the via electrode and before forming the first diffusion barrier film;
selectively removing the fourth inter-layer insulator in order to form a fifth opening on the via electrode after forming the via electrode and before forming the first diffusion barrier film; and
embedding a fifth conductive film on the fifth opening in order to form a fourth electrode, the fourth electrode connecting between the via electrode and the first electrode, after forming the via electrode and before forming the first diffusion barrier film.

18. The method for fabricating the semiconductor memory device of claim 16, wherein
the first diffusion barrier film is left on a sidewall of the first electrode along a word line direction in the selectively removing the first electrode and the first diffusion barrier film.

19. The method for fabricating the semiconductor memory device of claim 16, wherein
a size in the word line direction of the first electrode is larger than a size in a bit line direction of the first electrode and a size in the bit line direction of the second electrode is larger than a size in the word line direction of the second electrode.

20. The method for fabricating the semiconductor memory device of claim 16, further comprising;
forming a second diffusion barrier film on the third electrode, the ferroelectric film, the second electrode after the forming the third electrode.
